(19) United States
(12) Patent Application Publication
(10) Pub. No.: US 2025/0372364 A1
(43) Pub. Date: Dec. 4, 2025

(54) DEPOSITION OF POLYIMIDE MATERIAL

(71) Applicant: ASM IP Holding B.V., Almere (NL)

(72) Inventors: Varun Sharma, Helsinki (FI); Charles Dezelah, Helsinki (FI); Michael Givens, Scottsdale, AZ (US)

(21) Appl. No.: 19/220,249

(22) Filed: May 28, 2025

Related U.S. Application Data
(60) Provisional application No. 63/654,157, filed on May 31, 2024.

(51) Int. Cl. H01L 21/02

(52) U.S. Cl. CPC H01L 21/02216; H01L 21/02118; H01L 21/0228

(57) ABSTRACT

The present disclosure relates to methods and apparatuses for the manufacture of semiconductor devices. More particularly, the disclosure relates to methods and apparatuses for depositing a layer of a polyimide material on a substrate. The process comprises providing a substrate in a reaction chamber, providing a first vapor-phase precursor in the reaction chamber, and providing a second vapor-phase precursor in the reaction chamber.

### CROSS-REFERENCE TO RELATED APPLICATION(S)

This application claims the benefit of U.S. Provisional Application 63/654,157 filed on May 31, 2024, the entire contents of which is incorporated herein by reference.

### FIELD

The present disclosure relates to methods and apparatuses for the manufacture of semiconductor devices. More particularly, the disclosure relates to methods and apparatuses for depositing a polyimide material on a substrate.

### BACKGROUND

Semiconductor device fabrication processes generally use advanced deposition methods to deposit materials with desired properties. Organic polymer layers can be used, for example, as a starting point in semiconductor applications for amorphous carbon films or layers. As an example, polyimide-containing layers are valuable for their thermal stability and resistance to mechanical stress and chemicals. They have been described as passivation layers to allow selective deposition of different materials. Patterning is conventionally used in depositing different materials on semiconductor substrates. Selective deposition, which is receiving increasing interest among semiconductor manufacturers, could enable a decrease in the number of steps needed for conventional patterning, thereby reducing the cost of processing. Selective deposition could also allow enhanced scaling in narrow structures. Various alternatives for bringing about selective deposition have been proposed, and additional improvements are needed to expand the use of selective deposition in industrial-scale device manufacturing. Known polyimide layers, however, suffer from various suboptimal performance issues, such as low hardness and poor electrical performance (e.g., a breakdown voltage of about 5 mV/cm).

Vapor-phase deposition processes, such as chemical vapor deposition (CVD), vapor deposition polymerization (VDP), molecular layer deposition (MLD), and sequential deposition processes, such as atomic layer deposition (ALD) and cyclical vapor deposition (CVD), may be used to deposit organic polymer layers, such as polyimide layers. In such processes, the precursors used to deposit the material have an important role in the properties of the deposited layers. This, again, affects the material's usability when different materials are selectively deposited on different surface combinations.

In addition to the properties of the resulting deposited material, precursors differ in cost and availability, as well as differ in their physical properties, thereby affecting the ease of handling of the precursors, as well as the possible parameter range during deposition. Thus, a need exists in the art to not only improve deposited polyimide layers, but also broaden the selection of precursors for the deposition of polyimide layers.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of depositing a polyimide material on a substrate, to a polyimide layer, and to deposition assemblies for depositing a polyimide layer on a substrate.

In one aspect, there is disclosed a method for depositing a layer of polyimide material on a substrate by a cyclic deposition process, the process comprising: providing a substrate in a reaction chamber; providing a first vapor-phase precursor in the reaction chamber; and providing a second vapor-phase precursor in the reaction chamber, wherein the first and second vapor-phase precursors form the polyimide material,
wherein the first vapor-phase precursor comprises a precursor having the Formula (1):

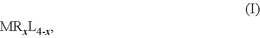

wherein M is a tetravalent element,
wherein x=0 to 4, preferably x=0 to 3,
wherein each R is independently selected from a group consisting of H, OH, a C₁ to C₄ alkyl group, a C₁ to C₄ alkoxide group; each L is independently E-R′—NH₂, wherein E is attached to M and E is selected from a group consisting of N, P, O, S, and Se, and R′ is a C₁ to C₁₀ hydrocarbon, and
wherein the second vapor-phase precursor comprises an organic precursor comprising at least two polymerization groups, each polymerization group comprising two carbonyl groups separated by a bridging atom. In some embodiments, the bridging atom is capable of reacting with the first vapor phase precursor.

In some embodiments, the first and second vapor-phase precursors form a polyimide material selectively on a first surface relative to a second surface. In some embodiments, by “selective deposition,” selectively depositing,” “selectively” or the like, it is meant that a greater amount of polyimide material is deposited at one location, e.g., a first surface, relative to a second location, e.g., a second surface.

In some embodiments, a predetermined thickness of polyimide material can be deposited on a first surface before growth is observed on a second surface. In some embodiments, at least 3 nm of polyimide material is grown on the first surface before growth is observed on the second surface. In some embodiments, at least 5 nm of polyimide material is grown on the first surface before growth is observed on the second surface. In some embodiments, at least 10 nm of polyimide material is grown on the first surface before growth is observed on the second surface. In some embodiments, at least 15 nm of polyimide material is grown on the first surface before growth is observed on the second surface. In some embodiments, at least 20 nm of polyimide material is grown on the first surface before growth is observed on the second surface.

As used herein, the term “polyimide material” refers to a material comprising polyimide. In some embodiments, more than approximately 50% of the polymer bonds in the polyimide material are polyimide bonds. In some embodiments, the properties of the polyimide material are substantially attributable to polyimide bonding in the polyimide material. In some embodiments, polyimide material consists substantially of, or consists of, polyimide. In some embodiments, polyimide material comprises polyimide and polyamide. In some embodiments, polyimide material comprises polyimide and polyamic acid.

It is understood that the elemental composition of the polyimide material depends on the precursors and deposition conditions used. In particular, a tetravalent element may be incorporated into the polyimide material and have an effect on the polyimide layer properties.

In the present disclosure, the first vapor-phase precursor comprises a precursor having the Formula (I):

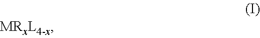

wherein M is a tetravalent element,
wherein x=0 to 4, preferably x=0 to 3,
wherein each R is independently selected from a group consisting of H, OH, a C₁ to C₄ alkyl group, a C₁ to C₄ alkoxide group; each L is independently E-R′—NH₂, wherein E is attached to M and E is selected from a group consisting of N, P, O, S, and Se, and R′ is a C₁ to C₁₀ hydrocarbon.

In some embodiments, M is a tetravalent element selected from metals or semimetals. In some embodiments, M is a tetravalent element is selected from a group consisting of C, Si, Ge, Hf, Zr, Mo, W, Ru, Te, and Ti. In some embodiments, M is Ge or Si.

In some embodiments, each R is an independently selected linear, branched, or cyclic C₁ to C₄ alkoxide group. In some embodiments, each R is an independently selected linear, branched, or cyclic C₁ to C₄ alkyl group. In particular embodiments, each R is a methyl. In some embodiments, at least two of the R groups are a methyl. In some embodiments, when R is an alkoxide, the R is attached to M through an oxygen of the alkoxy group.

In Formula (I), in some embodiments, x is 1 to 3. In some embodiments, x is 1 to 2. In some embodiments, x=0. In some embodiments, x=1. In some embodiments, x=2. In some embodiment, x=3. In some embodiments, x=4.

In some embodiments, in the formula L=E-R′—NH₂, E is selected from a group consisting of O, S, and Se. In some embodiments, E is O. In some embodiments, E is S. In some embodiments, E is Se.

In some embodiments, R′ is selected from a linear, branched, or cyclic C₁ to C₁₀ aliphatic group and aromatic hydrocarbons. In some embodiments, R′ is selected from CₘH₂ₘ where m is an integer from 1 to 10, for example R′ may be selected from CH₂, C₂H₄, C₃H₆, and the like.

In some embodiments, the first vapor-phase precursor comprises a precursor having the Formula (II):

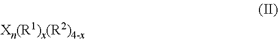

wherein each R¹ independently selected from a group consisting of H, Me, and OH, and H₂N—CₘH₂ₘ-G (where m=1 to 10),
wherein each R² is independently selected from a group consisting of H, Me, OH, and H₂N—CₘH₂ₘ-G (where m=1 to 10), and
wherein G=O, S, or P,
wherein at least one of the R¹ and R² groups is the H₂N—CₘH₂ₘ-G group,
wherein x=0 to 4, preferably x=0 to 3,
wherein n=1 to 10, and
wherein X=Si, Hf, or Ti.

In some embodiments, at least two of the R¹ and R² groups are the H₂N—CₘH₂ₘ-G groups. In particular embodiments, each R² is the H₂N—CₘH₂ₘ-G group and each R¹ is a methyl group.

In some embodiments, X=Si. In some embodiments, X=Ti. In some embodiments, X=Hf.

In some embodiments, the bridging atom is O. In some embodiments, the bridging atom is S. In some embodiments, the bridging atom is P.

In some embodiments, the CₘH₂ₘ of the group H₂N—CₘH₂ₘ-G is selected from CH₂, C₂H₄, C₃H₆, and the like.

In some embodiments, the first precursor has the formula of Formula (III):

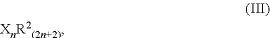

wherein X=Si, wherein n=1 to 4, wherein each R² is independently selected from H, Me, OH, and H₂N—CₘH₂ₘ-G (where m=1 to 10), wherein at least one R² group is H₂N—CₘH₂ₘ-G, and wherein G=O, S, or P. In some embodiments, at least two R² groups are H₂N—CₘH₂ₘ-G.

In some embodiments, the CₘH₂ₘ of the group H₂N—CₘH₂ₘ-G- is selected from CH₂, C₂H₄, C₃H₆, and the like.

In a particular embodiment, the first vapor-phase precursor comprises the following compound:

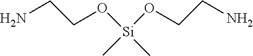

In some embodiments, the polyimide material comprises a polyimide material having Si, O, C, and N atoms.

In the present disclosure, the second vapor-phase precursor comprises an organic precursor comprising at least two polymerization groups, each polymerization group comprising two carbonyl groups separated by a bridging atom. In some embodiments, the bridging atom is capable of reacting with the first vapor-phase precursor.

In some embodiments, the bridging atom that is capable of reacting with the first vapor-phase precursor is oxygen. In some embodiments, the second vapor phase precursor comprises at least two bridging oxygen atoms.

In some embodiments, the second vapor-phase precursor comprises a member selected from the group consisting of dianhydrides, diacyl halides, diisocynates, diimides, dicarboxylic acids, and thioanhydrides.

In some embodiments, the second vapor-phase precursor comprises a dianhydride compound. In some embodiments, the dianhydride is an acetic dianhydride. In some embodiments, the dianhydride is a dithioanhydride. In some embodiments, the dianhydride is pyromellitic dithioanhydride. In some embodiments, the second reactant is an anhydride, such as furan-2,5-dione (maleic acid anhydride), or more particularly a dianhydride, e.g., pyromellitic dianhydride (PMDA), or any other monomer with at least two reactive groups which will react with the first vapor-phase precursor. In some embodiments, the second vapor-phase reactant comprises a dianhydride. In some embodiments, the second vapor-phase reactant comprises pyromellitic dianhydride (PMDA). In some embodiments, the second vapor-phase reactant comprises pyromellitic dithioanhydride.

In a particular embodiment, the second vapor-phase precursor comprises pyromellitic dianhydride (PMDA). Pyromellitic dianhydride is an organic compound with the formula C₆H₂(C₂O₃)₂.

In some embodiments, the second vapor-phase precursor comprises an acetic dianhydride comprising one carbon ring. In some embodiments, the second vapor-phase precursor comprises an acetic dianhydride comprising two carbon rings. In some embodiments, the second vapor-phase precursor comprises an acetic dianhydride comprising three carbon rings. In some embodiments, the acetic dianhydride is selected from a group of molecules represented by the following formulas (IVa, b, c, d, e, f, g from left to right):

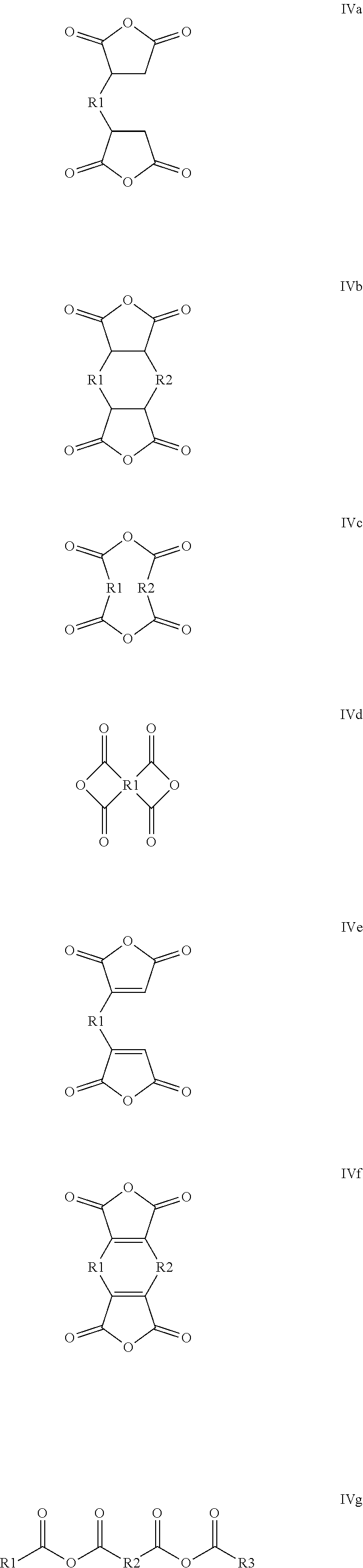

In each of Formulas IVa-g, each of R¹, R², and R³ can be independently selected from C₁ to C₆ hydrocarbons. In some embodiments, each of R¹, R², and R³ are independently selected from C₁ to C₆ hydrocarbons. In some embodiments, each of R¹, R², and R³ are independently selected from C₁ to C₄ hydrocarbons. In some embodiments, each of R¹, R², and R³ are independently selected from C₁ to C₃ hydrocarbons. With regards to formula IVa, preferably R¹ is a CH₂, C₂H₄, or a C₃H₆ group. Other related R¹ groups are possible. With regards to formula IVb, preferably R¹ and R² are each a CH₂, C₂H₄, or a C₃H₆ group. Other related R¹ and R² groups are possible. With regards to formula IVc, preferably R¹ and R² are each a CH₂, C₂H₄, or a C₃H₆ group. Other related R¹ and R² groups are possible. With regards to formula IVd, preferably R¹ is a carbon atom, a C—C group, or a CCH₂C group. Other related R¹ groups are possible. With regards to formula IVe, preferably R¹ is a CH₂, C₂H₄, or a C₃H₆ group. Other related R¹ groups are possible. With regards to formula IVf, preferably R¹ and R² are each a CH group. Other related R¹ and R² groups are possible. With regards to formula IVg, preferably R¹ is a C₁ to C₄ alkyl group and R² is a CH₂, C₂H₄, or a C₃H₆ group. Other related R¹ and R² groups are possible.

In some embodiments, the second vapor-phase precursor comprises a diacyl compound. In a particular embodiment, the diacyl compound comprises a member selected from a group consisting of isophthaloyl dichloride and terephthaloyl chloride.

In some embodiments, the second vapor-phase precursor comprises a diisocyanate compound. In a particular embodiment, the diisocyanate compound comprises a member selected from a group consisting of methylenebis(phenyl isocyanate), toluene diisocyanate, and hexamethylene diisocyanate.

In some embodiments, the second vapor-phase precursor comprises a dicarboxylic acid compound. In a particular embodiment, the dicarboxylic acid compound comprises a member selected from a group consisting of ispophthalic acid, terephthalic acid, oxalic acid, malonic acid, succinic acid, glutaric acid, and adipic acid.

In some embodiments, the formed layer of polyimide comprises a polyimide having Si, O, C, and N atoms.

In some embodiments, the polyimide material may be deposited on a first surface of the substrate to a greater degree than a second surface of the substrate.

In some embodiments, the substrate is held at a temperature higher than about 100° C. during the deposition process.

In some embodiments, the second surface comprises an inorganic dielectric surface. In some embodiments, the second surface is an inorganic dielectric surface. In some embodiments, the second surface comprises silicon. In some embodiments, the second surface comprises SiO₂.

In some embodiments, the polyimide material is deposited on the first surface relative to the second surface with a selectivity of above about 50%.

In some embodiments, the first surface comprises a metal oxide, elemental metal, or metallic surface. In some embodiments, the first surface comprises or consists essentially of a metal selected from a group consisting of aluminum, copper, tungsten, cobalt, nickel, niobium, iron, molybdenum, manganese, zinc, ruthenium, and vanadium.

In some embodiments, each deposition cycle further comprises removing excess of the first vapor-phase precursor and reaction by-products after providing the first vapor-phase precursor into the reaction chamber. In some embodiments, each deposition cycle further comprises removing excess of the second vapor-phase precursor and reaction by-products after providing the second vapor-phase precursor into the reaction chamber.

In some embodiments, all or substantially deposition cycles comprise removing excess precursors and/or reaction products.

In some embodiments, the method further comprises subjecting the substrate to an etch process subsequent to multiple consecutive deposition cycles, wherein the etch process removes substantially all of any deposited polyimide material from the second surface of the substrate and does not remove substantially all of the deposited polyimide material from the first surface of the substrate. In some embodiments, the etch process comprises exposing the substrate to hydrogen atoms, hydrogen radicals, hydrogen plasma, or combinations thereof. In some embodiments, the etch process comprises exposing the substrate to oxygen atoms, oxygen radicals, oxygen plasma, or combinations thereof.

In another aspect, there is disclosed a method of selectively depositing a polyimide material on a second surface of a substrate relative to a first surface of the substrate by a cyclic deposition process. In this aspect, the process comprises depositing a layer of polyimide material on the first surface by providing a substrate in a reaction chamber, providing a first vapor-phase precursor as described herein in the reaction chamber, and providing a second vapor-phase precursor as described herein in the reaction chamber and depositing the inorganic material on the second surface. The first and second vapor-phase precursors form the polyimide material selectively on the first surface relative to the second surface. The method further comprises depositing the inorganic material on the second surface, and at least partially removing the second vapor-phase precursor from the first surface.

In yet another aspect, a polyimide material layer produced by a cyclic deposition process is disclosed. In this aspect, the process comprises providing a substrate in a reaction chamber, providing a first vapor-phase precursor as described herein in the reaction chamber, and providing a second vapor-phase precursor as described herein in the reaction chamber. The first and second vapor-phase precursors form the polyimide material selectively on the first surface relative to the second surface.

In a further aspect, a deposition assembly for selectively depositing a layer of polyimide material on a substrate is disclosed. The deposition assembly comprises one or more reaction chambers constructed and arranged to hold the substrate, and a precursor injector system constructed and arranged to provide a first precursor as described herein and a second precursor as described herein into the reaction chamber in a vapor phase. The deposition assembly also comprises a first precursor vessel constructed and arranged to contain the first precursor and a second precursor vessel constructed and arranged to contain the second precursor, and the assembly is constructed and arranged to provide the first precursor and the second precursor via the precursor injector system to the reaction chamber to deposit a layer of polyimide material on the substrate.

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example, TIN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. In some embodiments, a substrate according to the current disclosure comprises two surfaces having different material properties.

As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

In some embodiments, a precursor is provided in a mixture of two or more compounds. In a mixture, the other compounds in addition to the precursor may be inert compounds or elements. In some embodiments, a precursor is provided in a composition. Compositions suitable for use as composition may be in the form of a solution or a gas under standard conditions.

As used herein, “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, certain variables (e.g., x, n, and m) are used in the chemical formulas to represent the number of atoms or groups within the compound. It will be understood that the variables correspond to an integer that is 0 or a non-zero integer.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1A is a block diagram of a process for depositing a polyimide material according to an aspect of the current disclosure.

FIG. 1B is a block diagram of another process for depositing a material according to an aspect the current disclosure which adds an etching step.

FIG. 2 is a schematic presentation of depositing a polyimide layer according to the current disclosure for the selective deposition of polyimide material to be used as passivation material to deposit another material.

FIG. 3 is a schematic presentation of a vapor deposition assembly according to an aspect of the current disclosure.

### DETAILED DESCRIPTION

The description of exemplary embodiments of methods, layers and deposition assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

A polyimide material according to the current disclosure is deposited on a substrate. A substrate has a surface. In some embodiments, the polyimide material according to the current disclosure is used as low-k dielectric material, i.e., as a component of a semiconductor device having a dielectric constant below that of silicon oxide. In some embodiments, the polyimide material according to the current disclosure is used for forming a spacer.

In some embodiments, the polyimide material is deposited on a substantially planar surface of the substrate. However, in some embodiments, the substrate surface has features, such as gaps, fins, or the like. In some embodiments, the polyimide material is deposited in a gap of a surface. A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap. A gap may comprise a top and a bottom. An upper part of a gap is the area at the opening of the gap, and the bottom of the gap is the part of the gap distal to the opening of the gap. The area outside the gap is termed the top surface of a gap, such as the topmost horizontal part of a fin, or an area of the substrate between holes or vias. The surface connecting the top and bottom of the gap is a sidewall.

The deposition of polyimide material may be conformal, such that the polyimide material covers the surface as a layer of substantially uniform thickness. In some embodiments, the deposition is conformal, but not entirely uniform, such that, for example, the layer of polyimide material may be thinner on the sidewall than at the top and/or bottom of the gap. In some embodiments, the polyimide material may be used to fill a gap at least partially. In some embodiments, the polyimide material according to the current disclosure is used for forming shallow trench isolation (STI). In some embodiments, the polyimide material according to the current disclosure is used for forming a PCRAM cell.

In some embodiments, the polyimide material according to the current disclosure may function as an etch-stop layer. In particular, the polyimide material may be resistant against plasma-based etching methods (also known as dry etch). In particular, polyimide material may be more resistant than some silicon-comprising materials against NF₃-containing plasma etch. Therefore, selective deposition of polyimide material according to the current disclosure may enable selective etching by NF₃-containing plasma. Thus, one or more of the materials present in the second surface are susceptible to etching by NF₃-containing plasma. It is to be understood that the term “NF₃-containing plasma” is an abbreviation for plasma generated from a gas mixture containing NF₃. The etching species in the reaction chamber may be variable active and reactive species.

In some embodiments, the NF₃-containing plasma further comprises at least one noble gas. The noble gas may be selected from a group consisting of helium (He), neon (Ne), argon (Ar), krypton (Kr) and xenon (Xe), and mixtures thereof. In some embodiments, the NF₃-containing plasma comprises argon (Ar). In some embodiments, the NF₃-containing plasma is generated from a gas mixture consisting substantially only of Ar and NF₃. In some embodiments, the NF₃-containing plasma comprises helium (He). In some embodiments, the NF₃-containing plasma is generated from a gas mixture consisting substantially only of He and NF₃. In some embodiments, the NF₃-containing plasma comprises Ar and He. In some embodiments, the NF₃-containing plasma is generated from a gas mixture consisting essentially of Ar, He, and NF₃. In embodiments, in which polyimide material is used as an etch stop layer, the second surface (i.e., the surface on which polyimide material is not deposited) comprises silicon. In some embodiments, the second surface comprises silicon oxide. In some embodiments, the second surface comprises one or more of SiO₂, SiN, SiC, SiCN, SiON, SiOC, and SiOCN.

According to some aspects of the present disclosure, selective deposition can be used to deposit a polyimide material on a first surface relative to a second surface. The two surfaces may have different material properties. In some embodiments, a polyimide material is selectively deposited on a first conductive (e.g., metal or metallic) surface of a substrate relative to a second dielectric surface of a substrate. In some embodiments, the first surface and the second surface are on the same substrate. In other embodiments, the first surface and the second surface are on different substrates.

In some embodiments, the second surface comprises hydroxyl (—OH) groups, such as a silicon oxide-based surface. In some embodiments, the second surface may additionally comprise hydrogen (—H) terminations, such as an HF-dipped Si or an HF-dipped Ge surface. In such embodiments, the surface of interest will be considered to comprise both the —H terminations and the material beneath the —H terminations. In some embodiments, a silicon polyimide material is selectively deposited on a first dielectric surface of a substrate relative to a second, different dielectric surface. In some such embodiments, the dielectrics have different compositions (e.g., silicon, silicon nitride, carbon, silicon oxide, silicon oxynitride, germanium oxide). In other such embodiments, the dielectrics can have the same basic composition (e.g., silicon oxide-based layers), but different material properties due to the manner of formation (e.g., thermal oxides, native oxides, deposited oxides). In some embodiments, vapor deposition methods are used.

After selective deposition of the polyimide is completed, further processing can be carried out to form the desired layers and/or structures. In some embodiments, cyclical vapor deposition is used, for example, cyclical vapor deposition (CVD) or atomic layer deposition (ALD) processes are used to deposit the desired layers and/or structures. In some embodiments, selectivity can be achieved without blocking agents on the surface to receive less of the polyimide material; and/or without catalytic agents on the surface to receive more of the polyimide material.

However, in some embodiments, blocking agents that prevent or reduce the deposition of the organic layer on the second surface are used. In some embodiments, silylation is used to block the second surface from deposition of polyimide material.

For embodiments in which a surface of the substrate comprises a metal, the surface is referred to as a metal surface. It may be a metal surface or a metallic surface. In some embodiments, the metal or metallic surface may comprise metal, metal oxides, and/or mixtures thereof. In some embodiments, the metal or metallic surface may comprise surface oxidation. In some embodiments, the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru, and W. In some embodiments, the metal or metallic surface comprises a transition metal selected from a group consisting of Zn, Fe, Mn, and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. In some embodiments, the metal or metallic surface may comprise one or more of ruthenium oxide, niobium oxide, niobium carbide, niobium boride, nickel oxide, cobalt oxide, tungsten nitrogen carbide, tantalum nitride or titanium nitride.

In some embodiments, the metal or metallic surface may be any surface that can accept or coordinate with the first or second precursor utilized in a selective deposition process as described herein.

In some embodiments, a polyimide material is selectively deposited on a metal oxide surface relative to another surface. The metal oxide surface may comprise, consist essentially of, or consist of, for example, a tungsten oxide (such as WO₃, WO₂, or W₂O₃), titanium oxide (such as TiO₂, Ti₂O₃, or TiO), aluminum oxide (such as Al₂O₃), or hafnium oxide (such as HfO₂) surface. In some embodiments, the metal oxide surface is an oxidized surface of a metallic material. In some embodiments, the metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the first surface may comprise a passivated metal surface, for example, a passivated Cu surface. That is, in some embodiments, the first surface may comprise a metal surface comprising a passivation layer, for example, an organic passivation layer such as a benzotriazole (BTA) layer.

In some embodiments, a polyimide material is selectively deposited on a first dielectric surface relative to a second SiO₂ surface. In some embodiments, a polyimide material is selectively deposited on a first dielectric surface relative to a second Si or Ge surface, for example an HF-dipped Si or HF-dipped Ge surface.

In some embodiments, a polyimide material is selectively deposited on a first metal or metallic surface of a substrate relative to a second dielectric surface of the substrate. In some embodiments, the first surface comprises a metal oxide, elemental metal, or metallic surface. The term “dielectric” is used in the description herein for the sake of simplicity in distinguishing from the other surface, namely the metal or metallic surface. It will be understood by the skilled artisan that not all non-conducting surfaces are dielectric surfaces. For example, the metal or metallic surface may comprise an oxidized metal surface that is electrically non-conducting or has a very high resistivity. Selective deposition processes taught herein can deposit on such non-conductive metallic surfaces with minimal deposition on adjacent dielectric surfaces.

In some embodiments, a polyimide material is selectively deposited on a first metal oxide surface of a substrate relative to a second surface. In some embodiment the first metal oxide surface may be, for example, a tungsten oxide, titanium oxide, aluminum oxide, hafnium oxide, or zirconium oxide surface. In some embodiments, the second SiO₂ surface may be, for example, a native oxide, a thermal oxide, or a chemical oxide. In some embodiments, a polyimide is selectively deposited on a first metal oxide surface relative to a second Si or Ge surface, for example, an HF-dipped Si or HF-dipped Ge surface.

In some embodiments, a substrate is provided comprising a first metal or metallic surface and a second dielectric surface. In some embodiments, a substrate is provided that comprises a first metal oxide surface. In some embodiments, the second surface may comprise-OH groups. In some embodiments, the second surface may be a SiO₂-based surface. In some embodiments, the second surface may comprise Si—O bonds. In some embodiments, the second surface may comprise a SiO₂-based, low-k material. In some embodiments, the second surface may comprise more than about 30%, preferably more than about 50% of SiO₂. In some embodiments, the second surface may comprise GeO₂. In some embodiments, the second surface may comprise Ge—O bonds. In some embodiments, a polyimide material is selectively deposited on a first metal or metallic surface relative to a second Si or Ge surface, for example, an HF-dipped Si or HF-dipped Ge surface.

In certain embodiments, the first surface may comprise a silicon dioxide surface and the second dielectric surface may comprise a second, different silicon dioxide surface. For example, in some embodiments, the first surface may comprise a naturally or chemically grown silicon dioxide surface. In some embodiments, the second surface may comprise a thermally grown silicon dioxide surface. In other embodiments, the first or the second surface may be replaced with a deposited silicon oxide layer. Therefore, in some embodiments, organic material may be selectively deposited on a first silicon dioxide surface of a substrate relative to a second silicon dioxide surface that was formed by a different technique and therefore has different material properties.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

In some embodiments, a blocking agent, such as silylating agent, is used to block the second surface before depositing the polyimide material on the first surface.

In some embodiments, a second surface, such as an oxide surface, on a substrate is blocked by silylation with a silylating agent, such as allyltrimethylsilane (TMS-A), bis(dimethylamino)dimethylsilane, bis(dimethylamino) diethylsilane, halosilane, for example chlorotrimethylsilane (TMS-Cl), octadecyltrichlorosilane (ODTCS), an imidazole, for example N-(trimethylsilyl) imidazole (TMS-Im), a silazane, for example hexamethyldisilazane (HMDS), a silylamine, for example or N-(trimethylsilyl)dimethylamine (TMSDMA) or 1,1,1-trimethoxy-N,N-dimethylsilanamine, or a pyrrole, such as 1-(triisopropylsilyl) pyrrole. and polyimide is selectively deposited on a first surface of the same substrate. The substrate may be contacted with a sufficient quantity of the blocking agent and for a sufficient period of time for the second surface to be selectively blocked with silicon species.

### Deposition Processes

The methods of depositing a polyimide material according to the current disclosure comprise providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of an atomic layer deposition (ALD) assembly. The reaction chamber can form part of a chemical vapor deposition (CVD) assembly. The deposition assembly may be an ALD or a CVD deposition assembly, but certain reaction chambers may be configured to perform methods of the current disclosure, which may be molecular layer deposition (MLD). In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

Selective deposition using the methods described herein can advantageously be achieved without treatment of the second surface to block deposition thereon and/or without treatment of the first surface (whether metallic or a different dielectric surface) to catalyze deposition. As a result, in some embodiments, the second dielectric surface does not comprise a passivation or blocking layer, such as a self-assembled monolayer (SAM), which would prevent the actual top surface of the second dielectric surface from being exposed to the chemicals of the deposition processes described herein. Thus, in some embodiments, selectivity is achieved despite the lack of blocking or catalyzing agents, and both first and second surfaces are directly exposed to the deposition precursors. Even in material pairs for which selectivity is not perfect, etch-back or similar corrective treatments using, for example, plasma, may allow selective deposition of polyimide material.

Vapor-phase deposition techniques can be applied to organic layers and polymers, such as polyimide films, polyamide films, polyurea films, polyurethane films, polythiophene films, and more. CVD or MLD of polymer films can produce greater thickness control, mechanical flexibility, conformal coverage, and biocompatibility as compared to the application of liquid precursors. Sequential deposition processing of polymers can produce high growth rates in small research scale reactors. Similar to CVD, sequential deposition processes can produce greater thickness control, mechanical flexibility, and conformality.

In some embodiments, the cyclic deposition process according to the current disclosure comprises a thermal deposition process. In thermal deposition, the chemical reactions are promoted by increased temperature relevant to ambient temperature. Generally, the temperature increase provides the energy needed for the formation of organic material, e.g., the silicon-polyimide material, in the absence of other external energy sources, such as plasma, radicals, or other forms of radiation.

In the current disclosure, the deposition process may comprise a cyclic deposition process, such as a cyclic chemical vapor deposition (CVD) process, molecular layer deposition (MLD), or a hybrid thereof irrespective of the reaction mechanism. The term “cyclic deposition process” (or sequential deposition) can refer to the sequential introduction of precursor(s) and/or reactant(s) into a reaction chamber to deposit material, such as the polyimide material, on a substrate. Cyclic deposition includes processing techniques, such as atomic layer deposition (ALD), cyclic chemical vapor deposition (cyclic CVD), and hybrid cyclic deposition processes. Hybrid cyclic deposition processes include features of at least two of the different cyclic deposition processes listed above. The cyclic deposition process may comprise a purge step between providing precursors into the reaction chamber.

As used herein, the term “purge” may refer to a procedure in which vapor-phase precursors and/or vapor-phase byproducts are removed from the substrate surface, for example, by evacuating the reaction chamber with a vacuum pump and/or by replacing the gas inside a reaction chamber with an inert or substantially inert gas, such as argon or nitrogen. Purging may be effected between two pulses of gases which react with each other. However, purging may be effected between two pulses of gases that do not react with each other. For example, a purge, or purging may be provided between pulses of two precursors. Purging may avoid or at least reduce gas-phase interactions between the two gases reacting with each other. It shall be understood that a purge can be effected either in time or in space, or both. For example, in the case of temporal purges, a purge step can be used e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Purging times may be, for example, from about 0.01 seconds(s) to about 20 seconds(s), from about 0.05 s to about 20 s, or from about 1 s to about 20 s, or from about 0.5 s to about 10 s, or between about 1 s and about 7 s, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

The process may comprise one or more cyclic phases. For example, pulsing of first precursor and second precursor may be repeated. In some embodiments, the process comprises or one or more acyclic phases. In some embodiments, the deposition process comprises the continuous flow of at least one precursor. In some embodiments, a precursor may be continuously provided in the reaction chamber. In such an embodiment, the process comprises a continuous flow of a precursor or a reactant. In some embodiments, one or more of the precursors and/or reactants are provided in the reaction chamber continuously.

In some embodiments, at least one of the first vapor-phase precursor and the second vapor-phase precursor is provided to the reaction chamber in pulses. In some embodiments, the first precursor is supplied in pulses and the second precursor is supplied in pulses, and the reaction chamber is purged between consecutive pulses of first precursor and second precursor.

A duration of providing first precursor and/or a second precursor into the reaction chamber (i.e. first precursor pulse time and second precursor pulse time, respectively) may be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of first precursor or a second precursor pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, first precursor pulse time may be at least 5 seconds, or at least 10 seconds. In some embodiments, first precursor pulse time may be at most 5 seconds, or at most 10 seconds or at most 20 seconds, or at most 30 seconds. In some embodiments, second precursor pulse time may be at least 5 seconds, or at least 10 seconds, or at least 20 seconds. In some embodiments, second precursor pulse time may be at most 5 seconds, or at most 10 seconds or at most 20 seconds, or at most 30 seconds.

The pulse times for first precursor, and for second precursor vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected first precursor and second precursor chemistries may influence suitable pulsing times. For process optimization purposes, shorter pulse times might be preferred as long as appropriate layer properties can be achieved. In some embodiments, first precursor pulse time is longer than second precursor pulse time. In some embodiments, second precursor pulse time is longer than first precursor pulse time. In some embodiments, first precursor pulse time is the same as second precursor pulse time.

In some embodiments, providing first precursor and/or a second precursor into the reaction chamber comprises pulsing the first precursor and the second precursor over a substrate. In certain embodiments, pulse times in the range of several minutes may be used for the first precursor and/or the second precursor. In some embodiments, first precursor may be pulsed more than one time, for example two, three or four times, before a second precursor is pulsed to the reaction chamber. Similarly, there may be more than one pulse, such as two, three or four pulses, of a second precursor before first precursor is pulsed (i.e., provided) into the reaction chamber.

Generally, in cyclic deposition processes according to the current disclosure, such as molecular layer deposition (MLD) or cyclic CVD, during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing second precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules. In some embodiments, the methods described herein are MLD methods.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. In some embodiments, the first precursor is supplied in pulses, the second precursor supplied in pulses and the reaction chamber is purged between consecutive pulses of first precursor and second precursor. Although, similar to ALD, CVD is often used to describe the deposition of inorganic materials, for the purposes of the current disclosure, CVD is to be understood to encompass the deposition of organic materials.

In some embodiments, the processes described herein may be batch processes, that is, the processes may be carried out on two or more substrates at the same time. In some embodiments, the processes described herein may be carried out on two or more, five or more, 10 or more, 25 or more, 50 or more, or 100 or more substrates at the same time. In some embodiments, the substrate may comprise wafers, for example, semiconductor or silicon wafers. In some embodiments, the substrates may have diameters of 100 mm or more, 200 mm or more, or 300 mm or more. In some instances, substrates having diameters of 450 mm or more may be desirable.

### Selectivity

Some embodiments of the current disclosure relate to a selective deposition process. Selectivity can be given as a percentage calculated by [(deposition on first surface)-(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%, greater than about 50%, greater than about 75%, greater than about 85%, greater than about 90%, greater than about 93%, greater than about 95%, greater than about 98%, greater than about 99% or even greater than about 99.5%. In some embodiments, the polyimide material is deposited on the first surface relative to the second surface with a selectivity of above about 50%. In embodiments described herein, the selectivity can change over the duration or thickness of a deposition. In some embodiments, selectivity increases with the duration of the deposition for the vapor-phase polymer depositions described herein. In contrast, typical selective deposition based on differential nucleation on different surfaces tends to become less selective with greater duration or thickness of a deposition.

In some embodiments, deposition occurs substantially only on the first surface and does not occur on the second surface. In some embodiments, deposition occurs substantially only on the first surface and does not occur on the second surface up to a thickness of at least about 3 nm, or of at least about 5 nm, or of at least about 10 nm, or of at least about 15 nm, or of at least about 20 nm. In some embodiments, deposition on the first surface of the substrate relative to the second surface of the substrate is at least about 80% selective, which may be selective enough for some particular applications. In some embodiments, the deposition on the first surface of the substrate relative to the second surface of the substrate is at least about 50% selective, which may be selective enough for some particular applications. In some embodiments, the deposition on the first surface of the substrate relative to the second surface of the substrate is at least about 10% selective, which may be selective enough for some particular applications.

In some embodiments, the organic film deposited on the first surface of the substrate may have a thickness less than about 50 nm, less than about 20 nm, less than about 10 nm, less than about 5 nm, less than about 3 nm, less than about 2 nm, or less than about 1 nm. In some embodiments, a ratio of material deposited on the first surface of the substrate relative to the second surface of the substrate may be greater than or equal to about 2:1, greater than or equal to about 20:1, greater than or equal to about 15:1, greater than or equal to about 10:1, greater than or equal to about 5:1, or greater than or equal to about 3:1.

In some embodiments, selective deposition is inherent, and no additional processing steps over those conveniently performed on a substrate are necessary. However, in some embodiments, the second surface may be passivated before depositing the material comprising molybdenum on the first surface. Selectivity may be inherent to a certain thickness of deposited material, and be lost in case deposition is continued beyond a process-specific threshold. Thus, it may be possible to deposit a material layer of, for example, about 1 nm, about 2 nm, about 3 nm, about 5 nm or about 6 nm before selectivity is lost. If thicker material layers are desired, the contrast between the first surface and the second surface may be enhanced though passivating the second surface. Alternatively or in addition, intermittent etch-back phase using, for example plasma, such as hydrogen plasma, may be used to keep selectivity.

### Selective Deposition

In some embodiments, a substrate comprising a first surface and a second surface is provided. The first and second surfaces may have different material properties. In some embodiments, the first surface may be a metallic surface and the second surface may be a dielectric surface. In some embodiments, a first precursor as disclosed herein is vaporized to form a first precursor vapor. The precursor being vaporized may be liquid or solid under standard temperature and pressure conditions (room temperature and atmospheric pressure). The substrate is then exposed to the first precursor vapor.

The substrate is also exposed to a second vapor-phase precursor, which may be an organic precursor comprising at least two polymerization groups, e.g., at least two oxygen-containing groups, such as carbonyl groups, as described herein, such as a dianhydride. The dianhydride may be, for example, pyromellitic dianhydride (PMDA). The cyclic exposure of the substrate to the two precursors leads to the deposition of polyimide material. The method can include additional steps, and may be repeated, but need not be performed in the illustrated sequence nor the same sequence in each repetition, and can be readily extended to more complex vapor deposition techniques.

In some embodiments, the polyimide material is deposited at temperatures below 190° C., and subsequently heat-treated at a temperature of about 190° C. or higher (such as 200° C. or 210° C.).

In some embodiments, the substrate is thermally annealed for a period of about 1 to about 15 minutes. In some embodiments, the substrate is thermally annealed at a temperature of about 200° C. to about 500° C. In some embodiments, the thermal anneal step comprises two or more steps in which the substrate is thermally annealed for a first period of time at a first temperature and then thermally annealed for a second period of time at a second temperature.

Additional treatments, such as heat or chemical treatment, can be conducted prior to, after, or between the processing steps described herein. For example, treatments may modify the surfaces or remove portions of the material on the substrate surfaces exposed at various stages of the process. In some embodiments, the substrate may be pretreated or cleaned prior to or at the beginning of the selective deposition of polyimide material. In some embodiments, the substrate may be subjected to a plasma cleaning process at, prior to, or at the beginning of the selective deposition of polyimide material.

In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition of polyimide material. In some embodiments, the substrate surface may be exposed to hydrogen plasma, radicals, or atomic species prior to or at the beginning of the selective deposition of polyimide material. In some embodiments, a pretreatment or cleaning process may be carried out in the same reaction chamber as a selective deposition of organic material; however, in some embodiments, a pretreatment or cleaning process may be carried out in a separate reaction chamber.

### Vapor Phase Precursors

In the present disclosure, the first vapor-phase precursor comprises a precursor having the Formula (I):

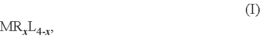

wherein M is a tetravalent element,
wherein x=0 to 4, preferably x=0 to 3,
wherein each R is independently selected from a group consisting of H, OH, a C₁ to C₄ alkyl group, a C₁ to C₄ alkoxide group; each L is independently E-R′—NH₂, wherein E is attached to M and E is selected from a group consisting of N, P, O, S, and Se, and R′ is a C₁ to C₁₀ hydrocarbon.

In some embodiments, M is a tetravalent element selected from metals or semimetals. In some embodiments, M is a tetravalent element is selected from a group consisting of C, Si, Ge, Hf, Zr, Mo, W, Ru, Te, and Ti. In some embodiments, M is Ge or Si.

In some embodiments, each R is an independently selected linear, branched, or cyclic C₁ to C₄ alkoxide group. In some embodiments, each R is an independently selected linear, branched, or cyclic C₁ to C₄ alkyl group. In particular embodiments, each R is a methyl. In some embodiments, at least two of the R groups are a methyl. In some embodiments, when R is an alkoxide, the R is attached to M through an oxygen of the alkoxy group.

In Formula (I), in some embodiments, x is 1 to 3. In some embodiments, x is 1 to 2. In some embodiments, x=0. In some embodiments, x=1. In some embodiments, x=2. In some embodiment, x=3. In some embodiments, x=4.

In some embodiments, in the formula L=E-R′—NH₂, E is selected from a group consisting of O, S, and Se. In some embodiments, E is O. In some embodiments, E is S. In some embodiments, E is Se.

In some embodiments, R′ is selected from a linear, branched, or cyclic C₁ to C₁₀ aliphatic group and aromatic hydrocarbons. In some embodiments, R′ is selected from CₘH₂ₘ where m is an integer from 1 to 10, for example R′ may be selected from CH₂, C₂H₄, C₃H₆, and the like.

In some embodiments, the first vapor-phase precursor comprises a precursor having the Formula (II):

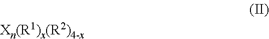

wherein each R¹ independently selected from a group consisting of H, Me, and OH, and H₂N—CₘH₂ₘ-G (where m=1 to 10),
wherein each R² is independently selected from a group consisting of H, Me, OH, and H₂N—CₘH₂ₘ-G (where m=1 to 10), and
wherein G=O, S, or P,
wherein at least one of the R¹ and R² groups is the H₂N—CₘH₂ₘ-G group,
wherein x=0 to 4, preferably x=0 to 3,
wherein n=1 to 10, and
wherein X=Si, Hf, or Ti.

In some embodiments, at least two of the R¹ and R² groups are the H₂N—CₘH₂ₘ-G groups. In particular embodiments, each R² is the H₂N—CₘH₂ₘ-G group and each R¹ is a methyl group.

In some embodiments, X=Si. In some embodiments, X=Ti. In some embodiments, X=Hf.

In some embodiments, the bridging atom is O. In some embodiments, the bridging atom is S. In some embodiments, the bridging atom is P.

In some embodiments, the CₘH₂ₘ of the group H₂N—CₘH₂ₘ-G is selected from CH₂, C₂H₄, C₃H₆, and the like.

In some embodiments, the first precursor has the formula of Formula (III):

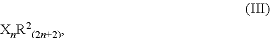

wherein X=Si, wherein n=1 to 4, wherein each R² is independently selected from H, Me, OH, and H₂N—CₘH₂ₘ-G (where m=1 to 10), wherein at least one R² group is H₂N—CₘH₂ₘ-G, and wherein G=O, S, or P. In some embodiments, at least two R² groups are H₂N—CₘH₂ₘ-G.

In some embodiments, the CₘH₂ₘ of the group H₂N—CₘH₂ₘ-G- is selected from CH₂, C₂H₄, C₃H₆, and the like.

In a particular embodiment, the first vapor-phase precursor comprises the following compound:

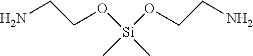

In some embodiments, the polyimide material comprises a polyimide material having Si, O, C, and N atoms.

In the present disclosure, the second vapor-phase precursor comprises an organic precursor comprising at least two polymerization groups, each polymerization group comprising two carbonyl groups separated by a bridging atom. In some embodiments, the bridging atom is capable of reacting with the first vapor-phase precursor.

In some embodiments, the bridging atom that is capable of reacting with the first vapor-phase precursor is oxygen. In some embodiments, the second vapor phase precursor comprises at least two bridging oxygen atoms.

In some embodiments, the second vapor-phase precursor comprises a member selected from the group consisting of dianhydrides, diacyl halides, diisocynates, diimides, dicarboxylic acids, and thioanhydrides.

The second vapor-phase precursor comprises an organic precursor comprising at least two polymerization groups, each polymerization group comprising two carbonyl groups separated by a bridging atom. In some embodiments, the bridging atom is capable of reacting with the first vapor-phase precursor.

In some embodiments, the second vapor-phase precursor comprises a dianhydride compound. In some embodiments, the dianhydride is an acetic dianhydride. In some embodiments, the dianhydride is a dithioanhydride. In some embodiments, the dianhydride is pyromellitic dithioanhydride. In some embodiments, the second reactant is an anhydride, such as furan-2,5-dione (maleic acid anhydride), or more particularly a dianhydride, e.g., pyromellitic dianhydride (PMDA), or any other monomer with at least two reactive groups which will react with the first vapor-phase precursor. In some embodiments, the second vapor-phase reactant comprises a dianhydride. In some embodiments, the second vapor-phase reactant comprises pyromellitic dianhydride (PMDA). In some embodiments, the second vapor-phase reactant comprises pyromellitic dithioanhydride.

In a particular embodiment, the second vapor-phase precursor comprises pyromellitic dianhydride (PMDA). Pyromellitic dianhydride is an organic compound with the formula C₆H₂(C₂O₃)₂.

In some embodiments, the second vapor-phase precursor comprises an acetic dianhydride comprising one carbon ring. In some embodiments, the second vapor-phase precursor comprises an acetic dianhydride comprising two carbon rings. In some embodiments, the second vapor-phase precursor comprises an acetic dianhydride comprising three carbon rings. In some embodiments, the acetic dianhydride is selected from a group of molecules represented by the following formulas (IVa, b, c, d, e, f, g from left to right):

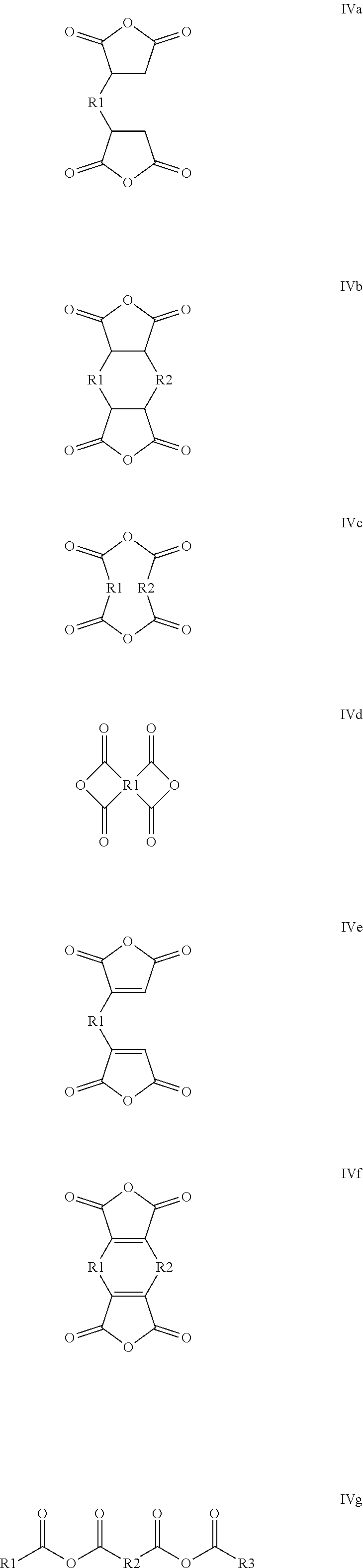

In each of Formulas IVa-g, each of R¹, R², and R³ can be independently selected from C₁ to C₆ hydrocarbons. In some embodiments, each of R¹, R², and R³ are independently selected from C₁ to C₆ hydrocarbons. In some embodiments, each of R¹, R², and R³ are independently selected from C₁ to C₄ hydrocarbons. In some embodiments, each of R¹, R², and R³ are independently selected from C₁ to C₃ hydrocarbons. With regards to formula IVa, preferably R¹ is a CH₂, C₂H₄, or a C₃H₆ group. Other related R¹ groups are possible. With regards to formula IVb, preferably R¹ and R² are each a CH₂, C₂H₄, or a C₃H₆ group. Other related R¹ and R² groups are possible. With regards to formula IVc, preferably R¹ and R² are each a CH₂, C₂H₄, or a C₃H₆ group. Other related R¹ and R² groups are possible. With regards to formula IVd, preferably R¹ is a carbon atom, a C—C group, or a CCH₂C group. Other related R¹ groups are possible. With regards to formula IVe, preferably R¹ is a CH₂, C₂H₄, or a C₃H₆ group. Other related R¹ groups are possible. With regards to formula IVf, preferably R¹ and R² are each a CH group. Other related R¹ and R² groups are possible. With regards to formula IVg, preferably R¹ is a C₁ to C₄ alkyl group and R² is a CH₂, C₂H₄, or a C₃H₆ group. Other related R¹ and R² groups are possible.

In some embodiments, the second vapor-phase precursor comprises a diacyl compound. In a particular embodiment, the diacyl compound comprises a member selected from a group consisting of isophthaloyl dichloride and terephthaloyl chloride.

In some embodiments, the second vapor-phase precursor comprises a diisocyanate compound. In a particular embodiment, the diisocyanate compound comprises a member selected from a group consisting of methylenebis(phenyl isocyanate), toluene diisocyanate, and hexamethylene diisocyanate.

In some embodiments, the second vapor-phase precursor comprises a dicarboxylic acid compound. In a particular embodiment, the diisocyanate compound comprises a member selected from a group consisting of ispophthalic acid, terephthalic acid, oxalic acid, malonic acid, succinic acid, glutaric acid, and adipic acid.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

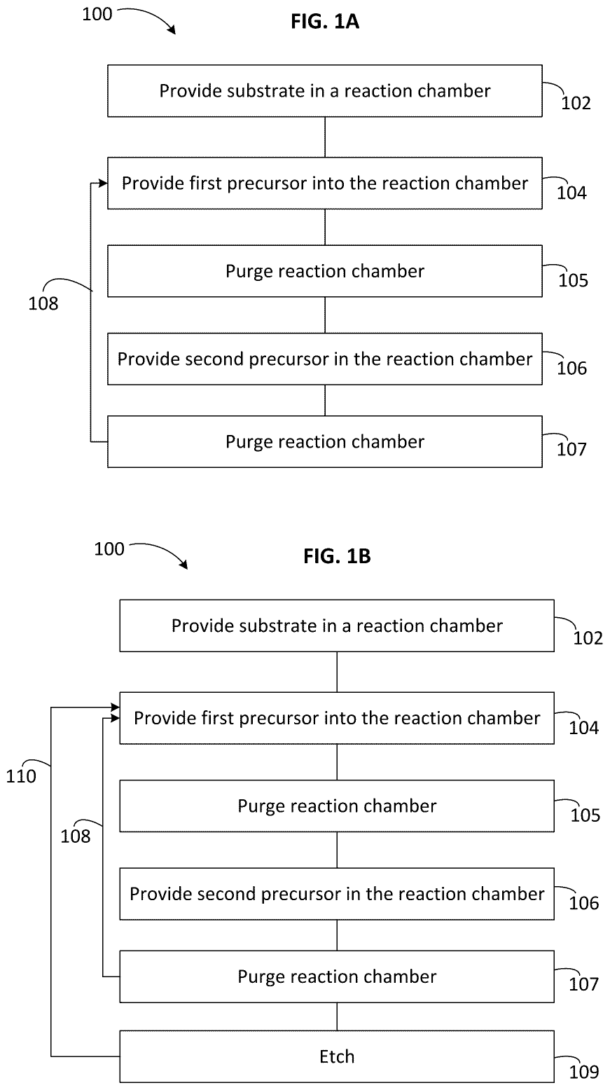

FIG. 1 depicts an aspect of the present invention, wherein a layer of polyimide material is deposited on a substrate by a cyclic deposition process. Referring to panel 1A, the process 100 comprises providing a substrate in a reaction chamber at block 102. A substrate according to the current disclosure comprises a surface. In some embodiments, the substrate comprises a first surface and a second surface, and the first and second surfaces have different material properties. In some embodiments, the first surface may be a conductive surface, for example, a metal or metallic surface (such as a Cu, Co, W, or Mo), and the second surface may be a dielectric surface (such as SiO₂, SiOC, SiN, or HfO₂).

In some embodiments, the second surface comprises an inorganic dielectric surface. In some embodiments, the second surface is an inorganic dielectric surface. In some embodiments, the second surface comprises silicon. In some embodiments, the second surface comprises SiO₂. In some embodiments, the second surface comprises a silicon oxide-based material, such as a metal silicate. In some embodiments, the second surface is a high-k surface, such as a hafnium oxide surface or a lanthanum oxide surface. In some embodiments, the second surface is an etch-stop layer. An etch-stop layer may comprise, for example, a nitride.

In some embodiments, the first surface may be a dielectric surface and the second surface may be a second, different dielectric surface. In some embodiments, the first and second surfaces may have the same basic composition, but may have different material properties due to different manners of formation (e.g., thermal oxide, deposited oxide, or native oxide). In some embodiments, the first surface is a silicon-comprising surface and the second surface is a silicon-comprising surface of different composition. For example, the first or the second surface may be a silicon oxide-based surface, such as silicon oxide or a metal silicate-comprising surface, while the other surface is a silicon nitride-based surface.

At block 104, a first vapor-phase precursor as disclosed herein is provided into the reaction chamber. For providing the first precursor into the reaction chamber in vapor phase, the first precursor is vaporized. In some embodiments, the first precursor is vaporized at a first temperature to form the first vapor-phase precursor. In some embodiments, the first precursor vapor is transported to the substrate through a gas line at a second temperature. In some embodiments, the second temperature is higher than the first temperature. In some embodiments, the substrate may be contacted with the first vapor-phase precursor at a third temperature. Thus, the reaction chamber temperature and/or the susceptor temperature may be different than the vaporization temperature and the gas line.

In some embodiments, the third temperature is higher than the first temperature. In some embodiments, the third temperature is higher than the second temperature. In some embodiments, the third temperature is higher than the first temperature and the second temperature. In some embodiments, the third temperature is a susceptor temperature. In some embodiments, the third temperature is a susceptor temperature and it is between about 100° C. and 400° C., such as about 150° C., about 200° C., about 250° C., about 300° C. or about 350° C. In some embodiments, the substrate is held at a temperature higher than about 100° C., such as higher than about 150° C., during the deposition process for depositing the polyimide material.

Without limiting the current disclosure to any specific theory, the deposition temperature, such as the reaction chamber temperature or the susceptor temperature, may influence the growth rate of the polyimide material and/or selectivity or the degree thereof. For example, the polyimide material growth rate may be from about 1 to about 10 Å/cycle.

It is further understood that it may also be possible to include a plasma step in a downstream deposition step or steps, since the polyimide material deposited on the first surface may be able to withstand plasma exposure without loss of its desired functionality. Alternatively or in addition, the polyimide material may be resistant to certain types of plasma treatments, and it can be used to protect the underlying material from a plasma treatment. In other words, the polyimide material may be used as an etch stop material.

When the first precursor is provided into the reaction chamber at block 104, it will become in contact with the substrate. Without limiting the current disclosure to any specific theory, the first precursor may be selectively chemisorbed on the first surface of the substrate relative to the second surface of the substrate. In some embodiments, the first vapor-phase precursor is provided into the reaction chamber at block 104 for a first exposure period (first precursor pulse time). In some embodiments, the first precursor pulse time is from about 0.01 seconds to about 60 seconds, about 0.05 seconds to about 30 seconds, about 0.1 seconds to about 10 seconds or about 0.2 seconds to about 5 seconds. The optimum exposure period can be determined experimentally based on the particular circumstances, such as substrate properties and the composition of the first surface and the second surface. In some embodiments, such as embodiments where batch reactors are used, exposure periods of greater than 60 seconds may be employed.

At block 105, the reaction chamber is purged of the first vapor-phase precursor and/or any reaction by-products. This phase of the process may be omitted in some embodiments. However, in some embodiments purging is used. In some embodiments, purging is performed by providing an inert gas, such as a carrier gas, into the reaction chamber for a period of time (purge time). In some embodiments, N₂ gas is used in purging. In some embodiments, purge time is from about 0.5 seconds to about 10 seconds, such as from about 1 second to about 5 seconds, for example 1 second, 2 seconds, 4 seconds, 6 seconds or 8 seconds.

At block 106, a second vapor-phase precursor as disclosed herein is provided into the reaction chamber. In some embodiments, the second precursor is an organic precursor as disclosed herein capable of reacting with adsorbed species of the first precursor under the deposition conditions disclosed herein.

In some embodiments, a second vapor-phase precursor is provided into the reaction chamber at block 106 for a second exposure period (second precursor pulse time). In some embodiments, the second precursor may be vaporized at a fourth temperature to form the second vapor-phase precursor. In some embodiments, the second precursor vapor is transported to the substrate through a gas line at a fifth temperature. In some embodiments, the fifth temperature is higher than the first temperature. In some embodiments, the second vapor-phase precursor is provided into the reaction chamber at a sixth temperature that is higher than the fourth temperature. In some embodiments, the sixth temperature is substantially the same as the third temperature.

In some embodiments, the first precursor is provided into the reaction chamber prior to the second vapor-phase precursor being provided into the reaction chamber. Thus, in some embodiments, a first vapor-phase precursor as disclosed herein is provided into the reaction chamber prior to providing the second vapor-phase precursor into the reaction chamber. However, in some embodiments, the second vapor-phase precursor is provided into the reaction chamber prior to providing the first vapor-phase precursor into the reaction chamber.

In the method, the first and second vapor-phase precursors form the polyimide material selectively on the first surface relative to the second surface, and the first vapor-phase precursor comprises a precursor as disclosed herein and the second precursor comprises an organic precursor as disclosed herein. Without limiting the current disclosure to any specific theory, the selectivity may be at least partially due to the preferential chemisorption of the first precursor on the first surface.

In an aspect, the polyimide material according to the current disclosure forms a layer of polyimide material. The formed polyimide material includes further atoms, not included in known polyimide films, e.g., Si, Hf, or Ti. Exemplary properties provided by the novel and inventive polyimide material disclosed herein and made by the processes disclosed herein vs. conventional polyimide materials and processes include but are not limited to: increased hardness; improved electrical values; increased thermal conductivity; and increased thermal stability.

In embodiments wherein the polyimide material is deposited on copper surfaces, copper migration into the polyimide material according to the current disclosure may be reduced. This offers advantages in the overall deposition procedure, such as improved passivation properties for the polyimide material against additional material deposition. In other words, the selectivity of further deposition processes on the second surface relative to the first surface covered by the polyimide material may be improved.

At block 107, the reaction chamber is purged of the second vapor-phase precursor and/or any reaction by-products. This phase of the process may be omitted in some embodiments. However, in some embodiments purging is used. In some embodiments, purging is performed by providing an inert gas, such as a carrier gas, into the reaction chamber for a period of time (purge time). In some embodiments, N₂ gas is used in purging. In some embodiments, purge time is from about 0.5 seconds to about 10 seconds, such as from about 1 second to about 5 seconds, for example 1 second, 2 seconds, 4 seconds, 6 seconds or 8 seconds.

The use of purge phases 105 and 107 is independently optional. Thus, both or either one of the phases 105 and 107 may be performed, and the parameters, such as duration and composition of the purge gas, may be independently selected. In some embodiments, each deposition cycle comprises removing excess of the first vapor-phase precursor and reaction by-products after providing the first vapor-phase precursor into the reaction chamber. In some embodiments, each deposition cycle comprises removing excess of the second vapor-phase precursor and reaction by-products after providing the second vapor-phase precursor into the reaction chamber. However, it is possible that a deposition process comprises one or more cycles in which the purge phase is omitted. Thus, for simplicity, in the context of purging, each deposition cycle may mean “substantially each deposition cycle.”

The selective deposition process according to the current disclosure is a cyclic process. The thickness of the deposited polyimide material layer is determined, in addition to the conditions during providing the first precursor and the second precursor into the reaction chamber, by the number of deposition cycles 108 performed. In some embodiments, a deposition cycle comprises phases 104 and 106. In some embodiments, a deposition cycle comprises phases 104 and 106, as well as one or both of 105 and 107. In some embodiments, a deposition cycle comprises phases 104, 105, 106 and 107. In some embodiments, the first precursor and the second precursor are provided into the reaction chamber alternately and sequentially.

In some embodiments, a deposition cycle may be repeated until a layer of polyimide material a desired thickness is selectively deposited. The selective deposition cycle can include additional steps, need not be in the same sequence nor identically performed in each repetition, and can be readily extended to more complex vapor deposition techniques. For example, a selective deposition cycle can include additional precursor or reactant supply processes, such as the supply and removal (relative to the substrate) of additional precursors or reactants in each cycle or in selected cycles. Though not shown, the processes may additionally comprise treating the deposited film to form or further form a polymer (for example, by UV treatment, annealing, or the like).

FIG. 1B depicts an embodiment in which the method further comprises subjecting the substrate to an etch process 109 subsequent to multiple consecutive deposition cycles. The process is performed as in the embodiment of panel 1A, including repeating the deposition cycle according to block 108. The etch process may be performed once at the end of the deposition process, or it can be performed intermittently after a predetermined number of deposition cycles, as depicted by block 110. After an etch process, the selective deposition of polyimide material may be continued.

In some embodiments, the etch process removes substantially all of any deposited polyimide material from the second surface of the substrate and does not remove substantially all of the deposited polyimide material from the first surface of the substrate. In some embodiments, the etch process comprises exposing the substrate to hydrogen atoms, hydrogen radicals, hydrogen plasma, or combinations thereof. In some embodiments, the etch process comprises exposing the substrate to oxygen atoms, oxygen radicals, oxygen plasma, or combinations thereof.

In some embodiments, the substrate may be subjected to an etch process to remove at least a portion of the deposited polyimide material. In some embodiments, an etch process subsequent to selective deposition of the polyimide material may remove deposited polyimide material from both the first surface and the second surface of the substrate. In some embodiments, the etch process may be isotropic.

In some embodiments, the etch process may remove the same amount, or thickness, of polyimide material from the first and second surfaces. That is, in some embodiments, the etch rate of the polyimide material deposited on the first surface may be substantially similar to the etch rate of the polyimide material deposited on the second surface. Due to the selective nature of the deposition processes described herein, the amount of polyimide material deposited on the second surface of the substrate may be substantially less than the amount of polyimide material deposited on the first surface of the substrate. Therefore, an etch process may completely remove deposited polyimide material from the second surface of the substrate while deposited polyimide material may remain on the first surface of the substrate.

In some embodiments, the etch process may comprise an etch process known in the art, for example a dry etch process, such as a plasma etch process. In some embodiments, the etch process may comprise exposing the substrate to hydrogen atoms, hydrogen radicals, hydrogen plasma, or combinations thereof. For example, in some embodiments, the etch process may comprise exposing the substrate to a plasma generated from H₂ using a power from about 10 W to about 5000 W, from about 25 W to about 2500 W, from about 50 W to about 500 W, or preferably from about 100 W to about 400 W.

The selected first and second precursors according to the current disclosure may be used to deposit polyimide material that is more resistant to an etch process, for example, to an etch process performed by hydrogen plasma as an etchant. This may be advantageous, as it may allow for easier tuning of an etching process, which again may enable a broader selectivity window.

In some embodiments, the etch process may comprise exposing the substrate to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may also comprise noble gas species, for example Ar or He species. In some embodiments, the plasma may consist essentially of noble gas species. In some embodiments, the plasma may comprise other species, for example, nitrogen atoms, nitrogen radicals, nitrogen plasma, or combinations thereof. In some embodiments, the etch process may comprise exposing the substrate to an etchant comprising oxygen, for example, O₃. In some embodiments, the substrate may be exposed to an etchant at a temperature of between about 30° C. and about 500° C., for example, between about 100° C. and about 400° C. In some embodiments, the etchant may be supplied in one continuous pulse or may be supplied in multiple shorter pulses. A purge phase may be performed between etching pulses.

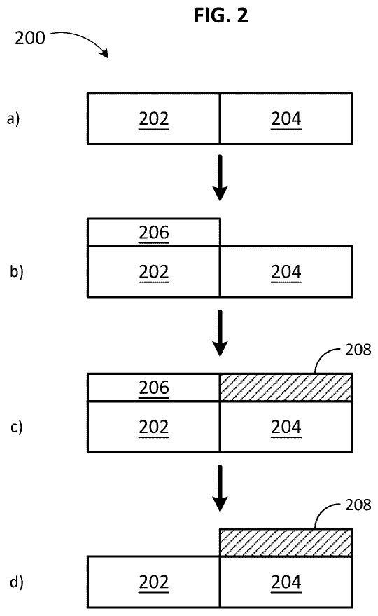

FIG. 2 depicts another aspect of the current disclosure in which inorganic material is selectively deposited on a second surface 204 of a substrate 200 relative to a first surface 202 of the substrate 200. At phase a), the substrate 200 is provided. The substrate 200 may be provided in a reaction chamber. A polyimide material 206 is deposited on the first surface 202 of the substrate 200 at phase b) according to a process as disclosed herein. The deposition process for depositing a layer of polyimide material 206 on the first surface 202 of the substrate 200 comprises providing a first vapor-phase precursor as disclosed herein in the reaction chamber, and providing a second vapor-phase precursor in the reaction chamber. The first and second vapor-phase precursors form a layer of polyimide material 206 selectively on the first surface 202 relative to the second surface 204.

Next, at phase c), an inorganic material 208 is deposited on the second surface 204. In some embodiments, the deposition of the inorganic material 208 may be performed by a cyclic deposition process, such as ALD or cyclic CVD. In some embodiments, the deposited inorganic material is a metal material, a metallic material, a dielectric material, or a combination thereof. In some embodiments, the deposited inorganic material is aluminum oxide. In some embodiments, the deposited inorganic material is a silicon-containing material. In some embodiments, the silicon-containing material is SiO₂, SiOC, SiN, a metal silicate-comprising material, or a combination thereof. For example, the deposited inorganic material may be yttrium-doped silicon oxide. In some embodiments, the deposited inorganic material is an oxide material. In some embodiments, the deposited material may be yttrium oxide-comprising material, zirconium oxide-comprising material, hafnium oxide-comprising material or a combination thereof. In some embodiments, the deposited inorganic material forms an etch-stop layer.

At phase d) of FIG. 2, the polyimide material 206 deposited on the first surface 202 is removed, leaving the deposited inorganic material on the second surface 204 and the original material of the first surface 202 as the topmost surfaces of the substrate. The above-mentioned phases can be followed by additional processing steps known in the art.

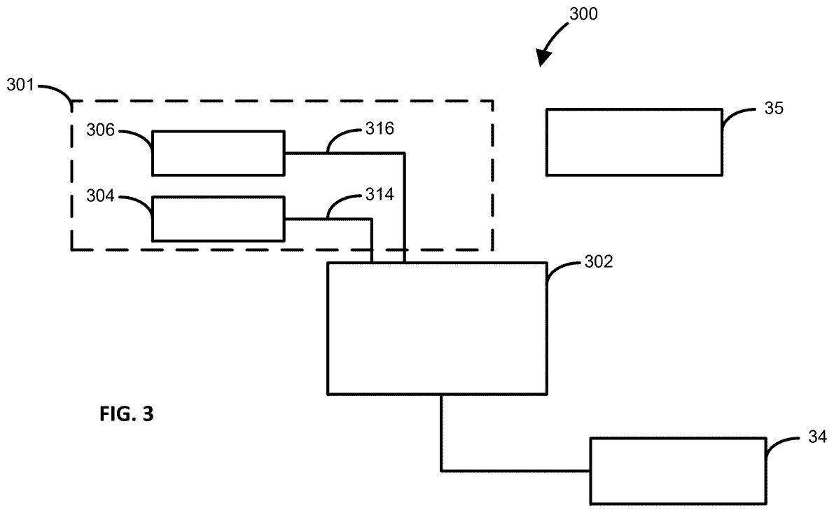

FIG. 3 illustrates a deposition assembly 300 according to the current disclosure in a schematic manner. Deposition assembly 300 can be used to perform a method as described herein and/or to deposit polyimide material as described herein.

In the illustrated example, deposition assembly 300 includes one or more reaction chambers 302, a precursor injector system 301, a first precursor vessel 304, a second precursor vessel 306, an exhaust source 34, and a controller 35. The deposition assembly 300 may comprise one or more additional gas sources (not shown), such as an inert gas source, a carrier gas source and/or a purge gas source. Reaction chamber 302 can include any suitable reaction chamber, such as an ALD or CVD reaction chamber as described herein.

The first precursor vessel 304 can include a vessel and one or more first precursors as described herein-alone or mixed with one or more carrier (e.g., inert) gases. A second precursor vessel 306 can include a vessel and one or more second precursors as described herein-alone or mixed with one or more carrier gases. Although illustrated with two source vessels 304, 306, a deposition assembly 300 can include any suitable number of source vessels. Source vessels 304, 306 can be coupled to reaction chamber 302 via lines 314 and 316, which can each include flow controllers, valves, heaters, and the like. In some embodiments, the first precursor in the first precursor vessel 304 and the second precursor in the second precursor vessel 306 may be heated. In some embodiments, a vessel is heated so that a precursor or a reactant reaches a temperature of at least about 30° C. or at least about 60° C. However, in some embodiments, the first precursor vessel is not heated. In some embodiments, the temperature of the first precursor in the first precursor vessel is regulated to be between about 15° C. and about 180° C., for example between about 15° C. and about 150° C.

Exhaust source 34 can include one or more vacuum pumps. Controller 35 includes electronic circuitry and software to selectively operate valves, manifolds, heaters, pumps and other components included in the deposition assembly 300. Such circuitry and components operate to introduce precursors, reactants and purge gases from the respective sources. Controller 35 can control timing of gas pulse sequences, temperature of the substrate and/or reaction chamber 302, pressure within the reaction chamber 302, and various other operations to provide proper operation of the deposition assembly 300. Controller 35 can include control software to electrically or pneumatically control valves to control flow of precursors, reactants and purge gases into and out of the reaction chamber 302. Controller 35 can include modules such as a software or hardware component, which performs certain tasks. A module may be configured to reside on the addressable storage medium of the control system and be configured to execute one or more processes.

Other configurations of deposition assembly 300 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 302. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 300, substrates, such as semiconductor wafers (not illustrated), are transferred from, e.g., a substrate handling system to reaction chamber 302. Once substrate(s) are transferred to reaction chamber 302, one or more gases from gas sources, such as precursors, reactants, carrier gases, and/or purge gases, are introduced into reaction chamber 302.

In a further aspect, a deposition assembly for selectively depositing a layer of organic material on a substrate is disclosed. The deposition assembly comprises one or more reaction chambers constructed and arranged to hold the substrate, and a precursor injector system constructed and arranged to provide a first precursor and a second precursor as disclosed herein into the reaction chamber in a vapor phase. The deposition assembly also comprises a precursor vessel constructed and arranged to contain the first precursor, and the assembly is constructed and arranged to provide the first precursor and the second precursor via the precursor injector system to the reaction chamber to deposit a layer of polyimide material on the substrate.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a layer of polyimide material on a substrate by a cyclic deposition process, the process comprising:
providing a substrate in a reaction chamber;
providing a first vapor-phase precursor in the reaction chamber; and
providing a second vapor-phase precursor in the reaction chamber,
wherein the first and second vapor-phase precursors react to form the layer of the polyimide material,
wherein the first vapor-phase precursor comprises a precursor having a structure according to Formula (I): 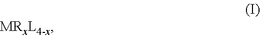
wherein M is a tetravalent element,
wherein x=0 to 3,
wherein each R is independently selected from a group consisting of H, OH, a C₁ to C₄ alkyl group, and a C₁ to C₄ alkoxide group; and each L is independently E-R′—NH₂, wherein E is attached to M and E is selected from a group consisting of N, P, O, S, and Se, and R′ is a C₁ to C₁₀ hydrocarbon, and
wherein the second vapor-phase precursor comprises an organic precursor comprising at least two polymerization groups, each polymerization group comprising two carbonyl groups separated by a bridging atom.

2. The method according to claim 1, wherein the tetravalent element is selected from metals or semimetals, and wherein the bridging atom is selected from O, S, or P.

3. The method according to claim 2, wherein the tetravalent element is selected from a group consisting of C, Si, Ge, Hf, Zr, Mo, W, Ru, Te, and Ti.

4. The method according to claim 3, wherein M is a Si or Ge.

5. The method according to claim 1, wherein x=2.

6. The method according to claim 1, wherein each R is independently selected from a linear, branched, or cyclic C₁ to C₄ alkoxide group and a linear, branched, or cyclic C₁ to C₄ alkyl group.

7. The method according to claim 6, wherein each R group is a methyl.

8. The method according to claim 1, wherein E is selected from a group consisting of O, S, and Se.

9. The method according to claim 1, wherein each R′ is independently selected from a linear, branched, or cyclic C₁ to C₁₀ aliphatic and aromatic hydrocarbons.

10. The method according to claim 1, wherein the first vapor-phase precursor comprises the compound:

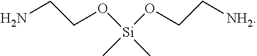

11. The method according to claim 1, wherein the polyimide material comprises Si, O, C, and N atoms.

12. The method according to claim 1, wherein the second vapor-phase precursor comprises a member selected from the group consisting of dianhydrides, diacyl halides, diisocynates, diimides, dicarboxylic acids, and thioanhydrides.

13. The method according to claim 1, wherein the second vapor-phase precursor comprises a compound selected from a group consisting of the following compounds (IVa-g): 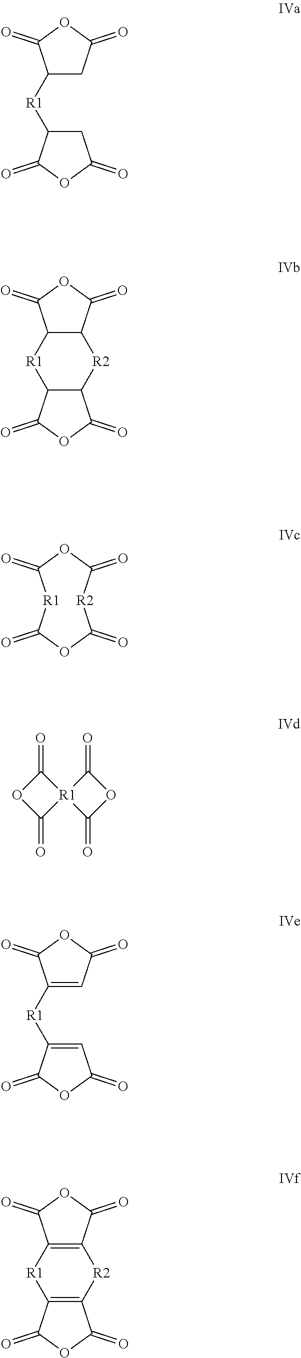 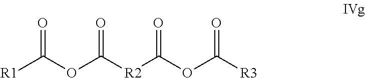
wherein each of R¹, R², and R³ in the compounds of Formula IVa-g can be independently selected from a C₁ to C₆ hydrocarbon.

14. The method according to claim 1, wherein the substrate is held at a temperature higher than about 100° C. during the deposition process.

15. The method according to claim 1, wherein the substrate comprises a first surface and a second surface, and wherein the polyimide material is selectively deposited on the first surface.

16. The method according to claim 15, wherein the second surface comprises an inorganic dielectric surface and the second surface comprises a metal.

17. A method for selectively depositing a layer of polyimide material on a substrate by a cyclic deposition process, the process comprising:
contacting a substrate comprising a first surface and a second surface with a first vapor-phase precursor; and
contacting the substrate with a second vapor-phase precursor,
wherein the first and second vapor-phase precursors react to form the polyimide material layer selectively on the first surface relative to the second surface;
wherein the first vapor-phase precursor comprises a precursor having a structure according to Formula (I): 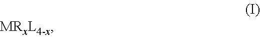
wherein M is a tetravalent element,
wherein x=0 to 3,
wherein each R is independently selected from a group consisting of H, OH, a C₁ to C₄ alkyl group, and a C₁ to C₄ alkoxide group; and each L is independently E-R′—NH₂, wherein E is attached to M and E is selected from a group consisting of N, P, O, S, and Se; and R′ is a C₁ to C₁₀ hydrocarbon, and
wherein the second vapor-phase precursor comprises an organic precursor comprising at least two polymerization groups, each polymerization group comprising two carbonyl groups separated by a bridging atom.

18. The method according to claim 17, wherein the second surface comprises an inorganic dielectric surface and the second surface comprises a metal.

19. The method according to claim 17, wherein, subsequent to the cyclic deposition process, the method further comprises subjecting the substrate to an etch process, wherein the etch process removes substantially all of a deposited organic material from the second surface of the substrate and does not remove the deposited organic material from the first surface of the substrate.

20. The method according to claim 19, wherein the etch process comprises exposing the substrate to a hydrogen plasma, an oxygen plasma, or a combination thereof.
